(19) United States
(12) Patent Application Publication
(10) Pub. No.: US 2005/0189617 A1
(43) Pub. Date: Sep. 1, 2005

(54) Bipolar transistor having multiple interceptors

(75) Inventors: Shoji Mizuno, Okazaki-city (JP); Akira Tai, Okazaki-city (JP); Takashi Nakano, Nukata-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/065,150

(22) Filed: Feb. 25, 2005

(30) Foreign Application Priority Data
Feb. 26, 2004 (JP) 2004-52127

(51) Int. Cl. H01L 27/082

(52) U.S. Cl. 257/565

(57) ABSTRACT

A bipolar transistor includes: a base having a first conductive type; an emitter having a second conductive type; a collector having the second conductive type; and a plurality of interceptors for intercepting a carrier path of a current in the base. The carrier path is disposed between the emitter and the collector through the base. Each interceptor is disposed on a shortest distance line of the carrier path in the base between the emitter and the collector. The carrier path is lengthened substantially without increasing the size of the transistor so that the transistor has a high withstand voltage. Further, the carrier path bypasses the interceptors so that the transport efficiency is not reduced substantially.

### CROSS REFERENCE TO RELATED APPLICATION

This application is based on Japanese Patent Application No. 2004-52127 filed on Feb. 26, 2004, the disclosure of which is incorporated herein by reference.

### FIELD OF THE INVENTION

The present invention relates to a bipolar transistor having multiple interceptors.

### BACKGROUND OF THE INVENTION

A bipolar transistor according to a prior art is disclosed in, for example, Japanese Patent Application Publication No. H05-166820. The bipolar transistor includes a base, an emitter and a collector. The base has the first conductive type, and the emitter and the collector have the second conductive type. A carrier of a current flows or moves between the emitter and the collector through the base.

Specifically, the emitter has a P conductive type, the base has a N conductive type and the collector has the P conductive type. The emitter, the base and the collector are formed on a surface portion of a semiconductor substrate. The carrier moves in a horizontal direction of the substrate so that the bipolar transistor provides a lateral type bipolar transistor.

It is required to increase a punch through withstand voltage between the collector and the emitter in a case where the bipolar transistor is operated. In the bipolar transistor, a distance between the emitter and the collector is set to be larger so that the withstand voltage of the transistor is increased. However, since the distance between the emitter and the collector is increased, the dimensions of the transistor become larger.

To increase the withstand voltage without increasing the size of the transistor, a high concentration region is formed in the base. The high concentration region has the N conductive type, and the impurity concentration of the high concentration region is higher than that of the base. In this case, since the high concentration region suppresses expansion of a depletion layer, which expands from the emitter or the collector, the withstand voltage of the transistor is increased. However, since the high concentration region is disposed in the base, a hole as a minority carrier injected from the emitter recombines with an electron at the high concentration region. Thus, transport efficiency is decreased so that transport performance of the transistor is reduced.

### SUMMARY OF THE INVENTION

In view of the above-described problem, it is an object of the present invention to provide a small size bipolar transistor having a high withstand voltage and high transport performance.

A bipolar transistor includes: a base having a first conductive type; an emitter having a second conductive type; a collector having the second conductive type; and a plurality of interceptors for intercepting a carrier path of a current in the base. The carrier path is disposed between the emitter and the collector through the base. Each interceptor is disposed on a shortest distance line of the carrier path in the base between the emitter and the collector.

In the above transistor, the carrier path is lengthened substantially without increasing the size of the transistor so that the transistor has a high withstand voltage. Further, the carrier path bypasses the interceptors so that the transport efficiency is not reduced substantially. Thus, the transistor with a small size has a high withstand voltage and high transport performance.

Preferably, each interceptor is a high concentration region having an impurity concentration higher than that of the base, and each interceptor has the first conductive type. Preferably, each interceptor is an insulation region.

Preferably, each interceptor has a predetermined shape so that the carrier path becomes a straight line for bypassing the interceptors, and the carrier path is tilted from the shortest distance line. Preferably, each interceptor has a predetermined shape so that the carrier path becomes a zigzag line for bypassing the interceptors.

Preferably, the interceptors are alternately aligned in two lines. Two lines are parallel each other, and two lines are perpendicular to the shortest distance line of the carrier path.

Further, an insulated gate bipolar transistor includes: a drift layer having a first conductive type; a base having a second conductive type and disposed in the drift layer; an emitter having the first conductive type and disposed in the base; a collector having the second conductive type and disposed in the drift layer; and a plurality of interceptors for intercepting a carrier path of a current in the drift layer. The carrier path is disposed between the emitter and the collector through the base and the drift layer, and each interceptor is disposed on a shortest distance line of the carrier path in the drift layer between the emitter and the collector.

In the above transistor, the carrier path is lengthened substantially without increasing the size of the transistor so that the transistor has a high withstand voltage. Further, the carrier path bypasses the interceptors so that the transport efficiency is not reduced substantially. Thus, the transistor with a small size has a high withstand voltage and high transport performance.

Preferably, the transistor further includes a gate disposed on the emitter, the base and the drift layer. The base and the collector are separated each other. The interceptors are alternately aligned in two lines. One line of the interceptors is disposed under the gate, and the other line of the interceptors is disposed between the collector and the gate.

### BRIEF DESCRIPTION OF THE DRAWINGS

The above and other objects, features and advantages of the present invention will become more apparent from the following detailed description made with reference to the accompanying drawings. In the drawings:

FIG. 1A is a plan view showing a bipolar transistor according to a first embodiment of the present invention, and FIG. 1B is a cross sectional view showing the transistor taken along line IB-IB in FIG. 1A;

FIG. 2A is a plan view showing a bipolar transistor according to a second embodiment of the present invention, and FIG. 2B is a cross sectional view showing the transistor taken along line IIB-IIB in FIG. 2A;

FIG. 3A is a plan view showing a bipolar transistor according to a third embodiment of the present invention, FIG. 3B is a cross sectional view showing the transistor taken along line IIIB-IIIB in FIG. 3A, and FIG. 3C is a cross sectional view showing the transistor taken along line IIIC-IIIC in FIG. 3A;

FIGS. 4A and 4B are plan views showing bipolar transistors according to a fourth embodiment of the present invention;

FIG. 5 is a plan view showing a bipolar transistor according to a fifth embodiment of the present invention;

FIG. 6 is a cross sectional view showing a bipolar transistor according to a sixth embodiment of the present invention;

FIG. 7A is a plan view showing a bipolar transistor according to a seventh embodiment of the present invention, FIG. 7B is a cross sectional view showing the transistor taken along line VIIB-VIIB in FIG. 7A, and FIG. 7C is a cross sectional view showing the transistor taken along line VIIC-VIIC in FIG. 7A; and

FIGS. 8A and 8B are plan views showing a bipolar transistor according to a comparison of the first embodiment.

### DETAILED DESCRIPTION OF THE PREFERRED EMBODIMENTS

### First Embodiment

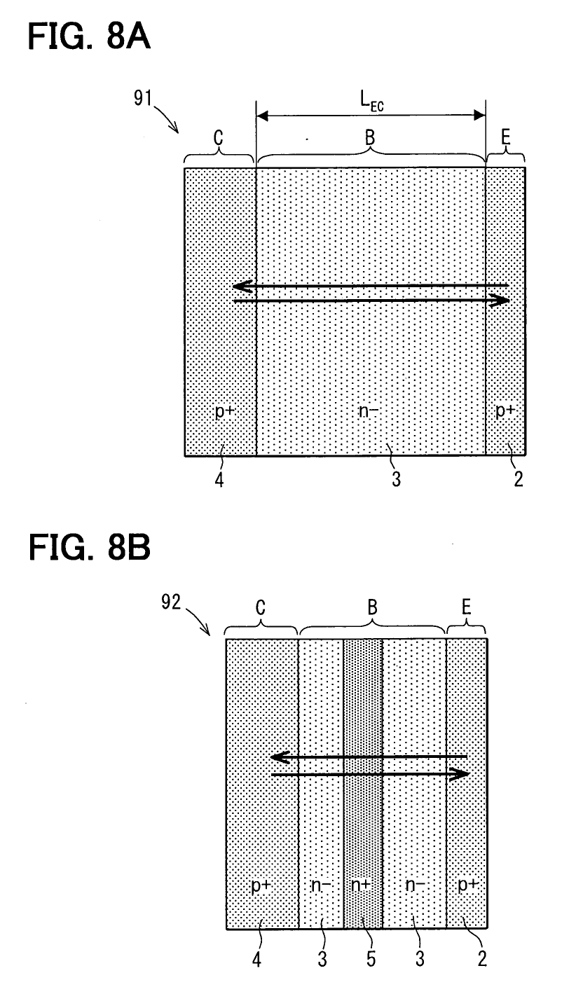

The inventors have preliminarily studied about a bipolar transistor. FIGS. 8A and 8B show the bipolar transistors 91, 92. The bipolar transistor 91 shown in FIG. 8A includes an emitter 2 having a P conductive type, a base 3 having a N conductive type and a collector 4 having a P conductive type. The emitter 2, the base 3 and the collector 4 are formed on a surface portion of a semiconductor substrate. A carrier of a current flows or moves in a horizontal direction of the substrate shown as an arrow in FIG. 8A. Thus, the bipolar transistor provides a lateral type bipolar transistor.

The bipolar transistor 92 shown in FIG. 8B also provides a lateral type bipolar transistor. Therefore, the carrier of the current moves in the horizontal direction of the substrate. The bipolar transistor 92 further includes a high concentration region 5 in the base 3. The high concentration region 5 has the N conductive type, and the impurity concentration of the high concentration region 5 is higher than that of the base 3. The high concentration region 5 has a stripe shape. The high concentration region 5 crosses a carrier path, i.e., a current path.

It is required to increase a punch through withstand voltage between the collector 4 and the emitter 2 in a case where the bipolar transistor is operated. In the bipolar transistor 91, a distance L_{EC} between the emitter 2 and the collector 4 is set to be larger so that the withstand voltage of the transistor 91 is increased. However, since the distance L_{EC} between the emitter 2 and the collector 4 is increased, the dimensions of the transistor 91 become larger.

In the transistor 92, the high concentration region 5 is formed in the base 3 to increase the withstand voltage of the transistor 92 without increasing the dimensions of the transistor 92. The high concentration region 5 suppresses expansion of a depletion layer, which expands from the emitter 2 or the collector 4. Thus, the withstand voltage of the transistor 92 is increased. However, since the high concentration region 5 is disposed in the base 3, a hole as a minority carrier injected from the emitter 2 recombines with an electron at the high concentration region 5. Thus, transport efficiency is decreased so that transport performance of the transistor 92 is reduced.

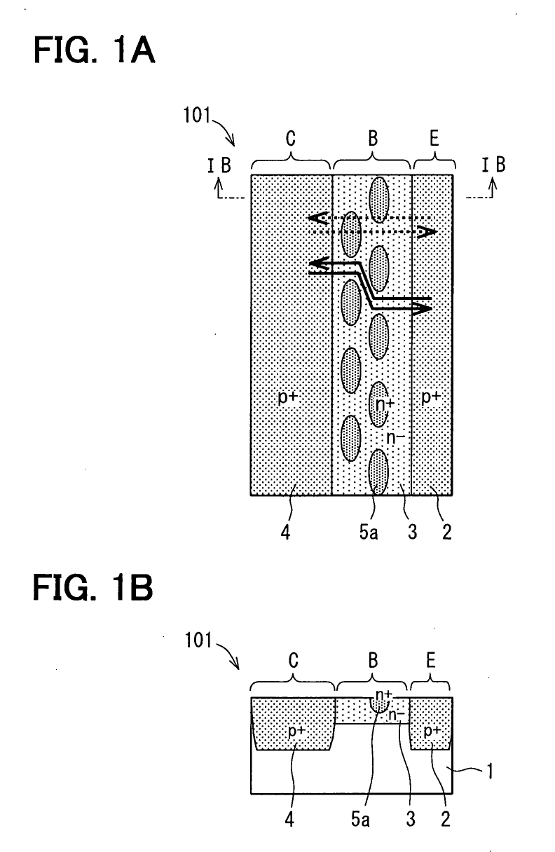

In view of the above problem, a bipolar transistor according to a first embodiment of the present invention is provided. The bipolar transistor 101 is shown in FIGS. 1A and 1B. The transistor 101 is a lateral type PNP bipolar transistor including a silicon substrate 1, an emitter 2, a base 3 and a collector 4. The emitter 2 has a P conductive type, i.e., the emitter 2 includes impurities having the P conductive type. The base 3 has a N conductive type, i.e., the base 3 includes impurities having the N conductive type. The collector 4 has the P conductive type. The emitter 2, the base 3 and the collector 4 are formed on one side of the surface portion of the substrate 1. An electron and a hole as a carrier of a current flow (i.e., move) in a lateral direction of the substrate 1 between the emitter 2 and the collector 4 through the base 3. Specifically, the carrier moves on the surface portion of the substrate 1.

A high concentration region 5a is formed in the base 3 of the transistor 101. The high concentration region 5a has the N conductive type, the impurity concentration of which is higher than that of the base 3. The high concentration region 5a is dotted in the base 3. Specifically, the high concentration region 5 is alternately aligned in two lines. Thus, the high concentration region 5a has multiple portions, which are disposed in two lines alternately. This construction of the high concentration region 5a is different from the high concentration region 5, which is formed to a stripe in the base 3 to cross the moving path of the carrier as shown in FIG. 8B. The high concentration region 5a in FIG. 1A intercepts the shortest moving distance line of the carrier moving between the emitter 2 and the collector 4, shown as a dotted lines in FIG. 1A. Therefore, the carrier moves along with a bended solid line.

Since the impurity concentration of the high concentration region 5a is higher than the base 3, the carrier is intercepted by the region 5a when the carrier moves through the base 3. Thus, the high concentration region 5a works as an interceptor. Here, the carrier in the lateral type bipolar transistor 101 mainly moves near the surface portion of the substrate 1. Therefore, it is no need for the high concentration region 5a to reach the bottom of the base 3. Although the base 3 is formed in the substrate 1 additionally, the surface portion of the substrate 1 itself can provide the base 3 by controlling the conductive type and the impurity concentration of the substrate 1 to be the same as those of the base 3.

The high concentration region 5a of the transistor 101 is easily formed by an ion implantation method. Accordingly, the manufacturing cost of the transistor is not increase with a formation of the high concentration region 5a.

In the transistor 101, the carrier path in the base 3 in a case where the transistor 101 breaks down because of a punch through phenomenon is different from that in a case where the transistor 101 is operated normally. When the punch through phenomenon is occurred so that the transistor 101 breaks down, the carrier attempts to move along with the dotted line in FIG. 1A disposed between the emitter 2 and the collector 4. However, the high concentration region 5a is disposed on the shortest moving distance line of the carrier; and therefore, the punch through phenomenon of the carrier is prevented from occurring. Specifically, since the high concentration region 5a as the interceptor of the carrier is formed in the base 3, the carrier path is lengthened substantially so that the effect of the high concentration region 5a is the same as a case where the distance between the emitter 2 and the collector 3 becomes longer. Thus, the high concentration region 5a suppresses an expansion of a depletion layer expanding from the emitter 2 or the collector 3 in a case where the transistor 101 is operated inversely (i.e., the withstand voltage is applied to the transistor 101), since the high concentration region 5a works as a stopper of the depletion layer. Thus, the transistor 101 has a high withstand voltage.

On the other hand, when the transistor 101 is operated normally, the carrier can move between the emitter 2 and the collector 4 along with the solid line shown in FIG. 1A so that the carrier bypasses the high concentration region 5a. Thus, a part of the holes as a minority carrier charged from the emitter 2 recombines with electrons at the high concentration region 5a. The other part of the holes reaches the collector without recombining with the electrons. Accordingly, the transport efficiency of the carrier in the base 3 is not reduced substantially by the high concentration region 5a so that the transistor performance of the transistor 101 is improved when the transistor 101 is operated normally.

Thus, the transistor 101 shown in FIGS. 1A and 1B has a high withstand voltage without increasing the dimensions of the transistor 101. Further, the transistor 101 has sufficient transport efficiency.

Although the transistor 101 is the PNP bipolar transistor, the transistor 101 can be a lateral type NPN bipolar transistor. In this case, the high concentration region 5a as the interceptor in the base 3 has the same conductive type as the base 3, and the impurity concentration of the high concentration region 5a is higher than that of the base 3.

Although the substrate 1 is a N conductive type silicon substrate, the substrate 1 can be a N conductive type semiconductor layer in a SOI (i.e., silicon on insulator) substrate.

The substrate 1 can be a SOI substrate, a substrate having an epitaxial semiconductor layer or the like. The bipolar transistor 101 can be separated with a trench. Further, the transistor 101 can be separated with a PN junction separation.

### Second Embodiment

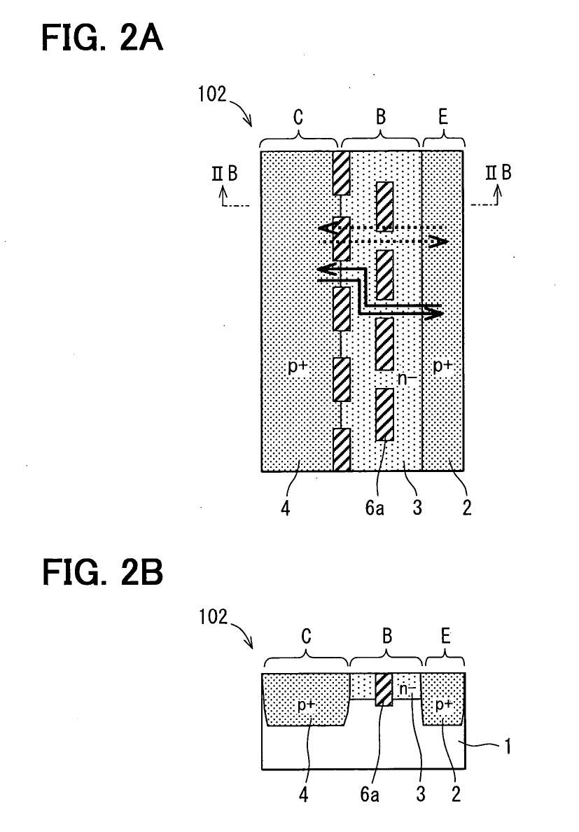

A bipolar transistor 102 according to a second embodiment of the present invention is shown in FIGS. 2A and 2B. The transistor 102 includes an insulation region 6a instead of the high concentration region 5a. The insulation region 6a works as the interceptor in the base 3 so that the carrier is prevented from moving along with the shortest moving distance path. The insulation region 6a reaches to the bottom of the base 3 in the vertical direction of the substrate 1. However, it is no need for the insulation region 6a to reach the bottom of the base 3, since the carrier moves near the surface portion of the substrate 1 in the lateral type bipolar transistor 102.

The insulation region 6a is preferably made of an oxide film. In this case, the insulation region 6a is, for example, formed of a sidewall oxide film embedded in a trench. This insulation region 6a is easily formed by a conventional semiconductor process. Accordingly, the manufacturing cost of the transistor 102 with adding a process of forming the insulation region 6a is not increased substantially.

In the transistor 102, the carrier path in the base 3 in a case where the transistor 102 breaks down because of the punch through phenomenon is different from that in a case where the transistor 102 is operated normally. When the punch through phenomenon is occurred so that the transistor 102 breaks down, the carrier attempts to move along with the dotted line in FIG. 2A disposed between the emitter 2 and the collector 4. However, the insulation region 6a is disposed on the shortest moving distance line (i.e., the dotted line) of the carrier; and therefore, the punch through phenomenon of the carrier is prevented from occurring. Specifically, since the insulation region 6a as the interceptor of the carrier is formed in the base 3, the carrier path is lengthened substantially so that the effect of the insulation region 6a is the same as a case where the distance between the emitter 2 and the collector 3 becomes longer. Thus, the insulation region 6a suppresses an expansion of a depletion layer expanding from the emitter 2 or the collector 3 in a case where the transistor 102 is operated inversely (i.e., the withstand voltage is applied to the transistor 102), since the insulation region 6a works as a stopper of the depletion layer. Thus, the transistor 102 has a high withstand voltage.

On the other hand, when the transistor 102 is operated normally, the carrier can move between the emitter 2 and the collector 4 along with the solid line shown in FIG. 2A so that the carrier bypasses the insulation region 6a. Thus, no part of the holes as a minority carrier charged from the emitter 2 recombines with electrons at the insulation region 6a. Accordingly, the transport efficiency of the carrier in the base 3 is not reduced by the insulation region 6a so that the transistor performance of the transistor 102 is improved when the transistor 102 is operated normally.

Thus, the transistor 102 shown in FIGS. 2A and 2B has a high withstand voltage without increasing the dimensions of the transistor 102. Further, the transistor 102 has sufficient transport efficiency.

### Third Embodiment

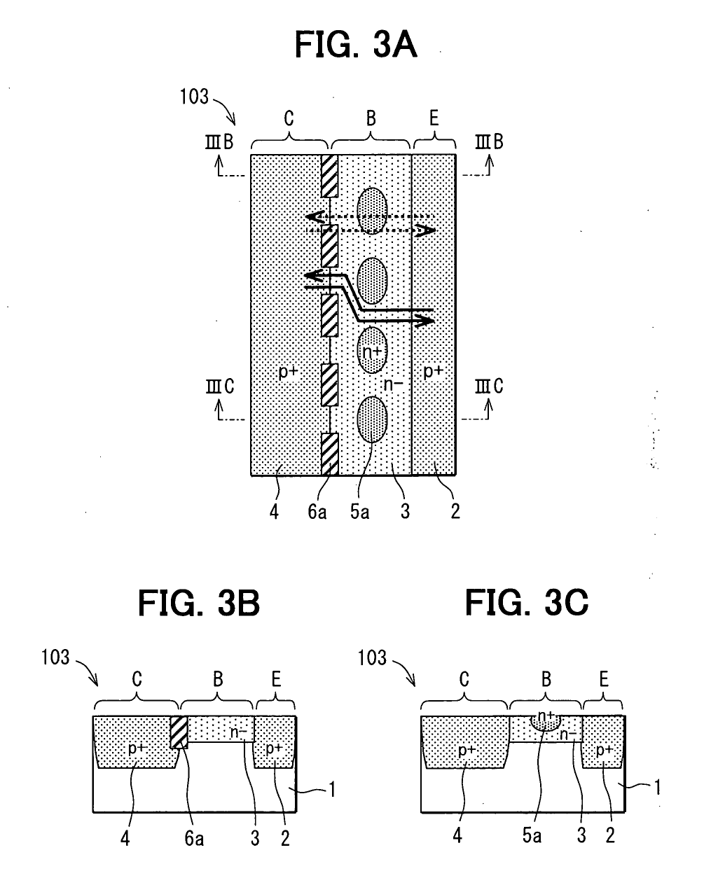

A bipolar transistor 103 according to a third embodiment of the present invention is shown in FIGS. 3A to 3C. The transistor 103 includes the insulation region 6a and the high concentration region 5a. Both of the insulation region 6a and the high concentration region 5a work as the interceptor of the carrier so that the transistor 103 has a high withstand voltage without increasing the dimensions of the transistor 103. Further, the transistor 103 has sufficient transport efficiency.

### Fourth Embodiment

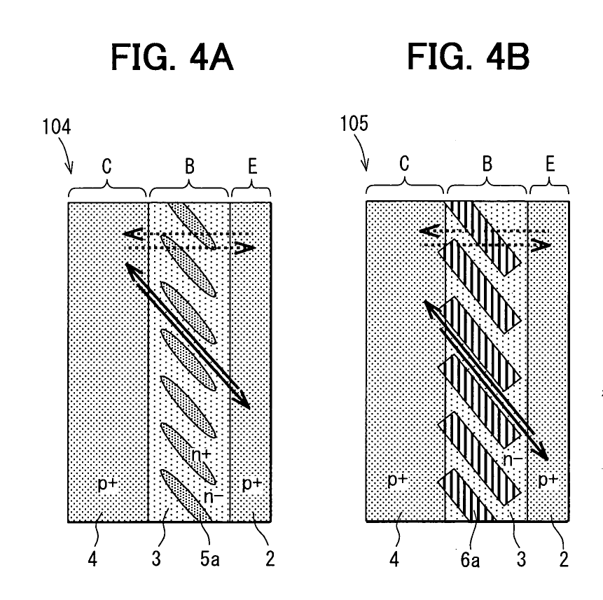

Bipolar transistors 104 and 105 according to a fourth embodiment of the present invention are shown in FIGS. 4A and 4B. The transistor 104 includes the high concentration region 5a having an elliptical shape, a long axis of which is tilted from the shortest moving distance line. Thus, the carrier path is lengthened by the high concentration region 5a so that the high concentration region 5a works as the interceptor of the carrier. Thus., the transistor 104 shown in FIG. 4A has a high withstand voltage without increasing the dimensions of the transistor 104. Further, the transistor 104 has sufficient transport efficiency.

The transistor 105 includes the insulation region 6a having an elliptical shape, a long axis of which is tilted from the shortest moving distance line. Thus, the, carrier path is lengthened by the insulation region 6a so that the insulation region 6a works as the interceptor of the carrier. Thus, the transistor 105 shown in FIG. 4B has a high withstand voltage without increasing the dimensions of the transistor 105. Further, the transistor 105 has sufficient transport efficiency.

In the transistors 104, 105, each carrier path shown as the solid line is a straight line with no bending portion so that the transistor 104, 105 can be designed easily.

### Fifth Embodiment

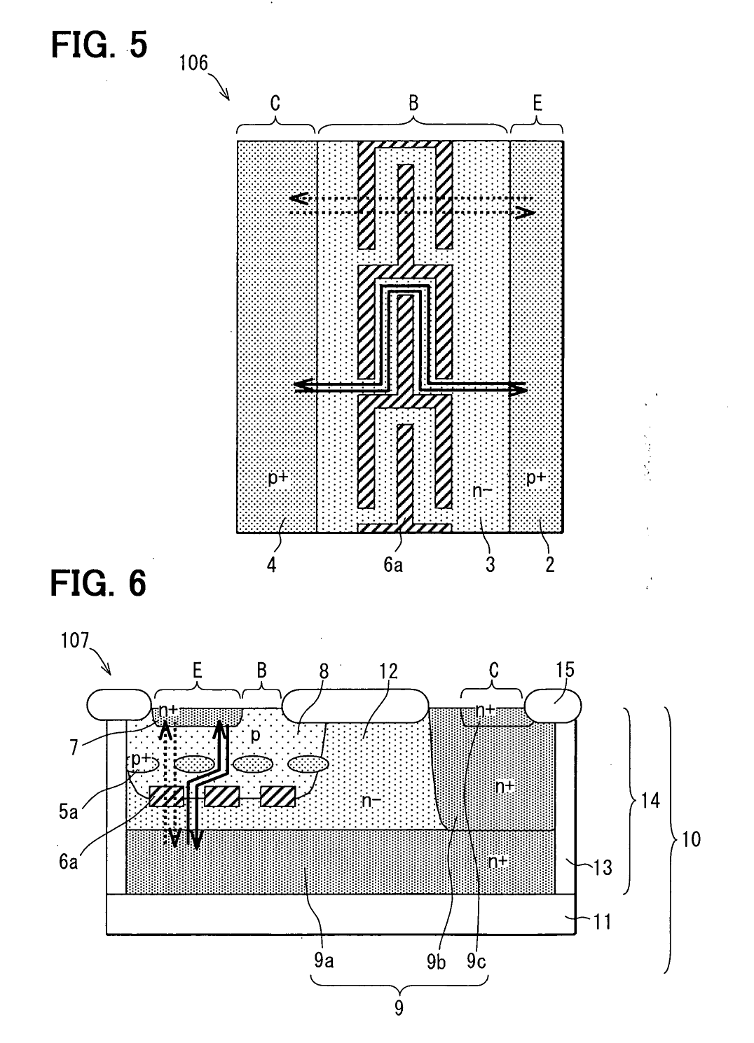

A bipolar transistor 106 according to a fifth embodiment of the present invention is shown in FIG. 5. The transistor 106 includes the insulation region 6a having a concavity and convexity shape in the base 3. In the transistor 106, the carrier moves along with the solid line in FIG. 5 to bypass the insulation region 6a as the interceptor so that the carrier path becomes a zigzag path between the emitter 2 and the collector 4. Accordingly, even when the distance between the emitter 2 and the collector 4 is narrow, the carrier path can be lengthened. Therefore, the dimensions of the transistor 106 become smaller. Further, the transistor 106 has a high withstand voltage and sufficient transport efficiency.

### Sixth Embodiment

A bipolar transistor 107 according to a sixth embodiment of the present invention is shown in FIG. 6. The transistor 107 is a vertical type NPN bipolar transistor having an emitter 7, a base 8 and a collector 9. The emitter 7 has the N conductive type, the base 8 has the P conductive type, and the collector 9 has the N conductive type. The collector 9 includes a diffusion layer 9a, a deep diffusion region 9b and a shallow diffusion region 9c. The emitter 7, the base 8 and the diffusion layer 9a as the collector 9 are formed in a substrate 10 in the vertical direction. Therefore, the carrier moves in the vertical direction of the substrate 10.

The substrate 10 is formed of a SOI (i.e., silicon on insulator) substrate having an embedded oxide layer 11. The transistor 107 is formed in a N conductive type semiconductor layer 14 disposed on one side of the SOI substrate 10. The diffusion layer 9a substantially works as the collector 9. The diffusion layer 9a is disposed on the embedded oxide layer 11. The diffusion layer 9a connects to the shallow diffusion region 9c through the deep diffusion region 9b. The shallow diffusion region 9c is disposed on the same surface as the emitter 7 and the base 8. The N conductive type semiconductor layer 14 includes a trench separation region 12, a separation trench 13 and a LOCOS (i.e., local oxidation of silicon) region 15.

The transistor 107 further includes the high concentration region 5a and the insulation region 6a in the base 8. The high concentration region 5a and the insulation region 6a work as the interceptor of the carrier so that the transistor 107 has a high withstand voltage and sufficient transport efficiency. Further, the thickness of the base 8 can be thinner.

Although the transistor 107 is the NPN bipolar transistor, the transistor 101 can be a lateral type PNP transistor. In this case, the high concentration region 5a as the interceptor in the base 8 has the same conductive type as the base 8, and the impurity concentration of the high concentration region 5a is higher than that of the base 8.

### Seventh Embodiment

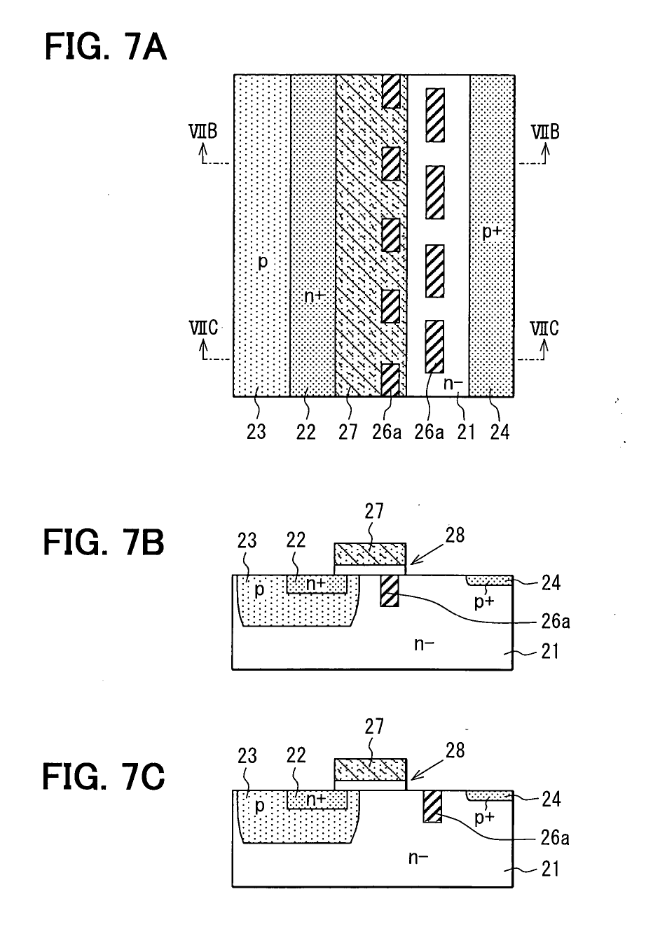

A lateral type IGBT (i.e., insulated gate bipolar transistor) 108 according to a seventh embodiment of the present invention is shown in FIGS. 7A to 7C. The IGBT 108 includes a N⁻ conductive type drift layer 21, a N⁺ conductive type emitter 22, a P conductive type base 23, a P⁺ conductive type collector 24, and a gate 27. The emitter 22 is formed in the base 23. The base 23 with the emitter 22 is formed in the drift layer 21. The collector 24 is also formed in the drift layer 21. The base 23 and the collector 24 are separated each other. The gate 27 is disposed on the drift layer 21 through an insulation film 28 as a gate oxide film. The carrier path of the transistor 108 is disposed near the surface portion of the drift layer 21. Therefore, an insulation region 26a as an embedded oxide film in a trench is formed on the surface portion of the drift layer 21. The insulation region 26a works as the interceptor of the carrier. Thus, the transistor 108 has a high withstand voltage and sufficient transport efficiency.

Such changes and modifications are to be understood as being within the scope of the present invention as defined by the appended claims.

1. A bipolar transistor comprising:
a base having a first conductive type;
an-emitter having a second conductive type;
a collector having the second conductive type; and
a plurality of interceptors for intercepting a carrier path of a current in the base, wherein
the carrier path is disposed between the emitter and the collector through the base, and
each interceptor is disposed on a shortest distance line of the carrier path in the base between the emitter and the collector.

2. The transistor according to claim 1, wherein
each interceptor is a high concentration region having an impurity concentration higher than that of the base, and
each interceptor has the first conductive type.

3. The transistor according to claim 1, wherein
the interceptors include insulation regions and high concentration regions, and
the high concentration regions have the first conductive type with an impurity concentration higher than that of the base.

4. The transistor according to claim 1, wherein
each interceptor is an insulation region.

5. The transistor according to claim 4, wherein
the insulation region is made of an oxide film.

6. The transistor according to claim 1, wherein
each interceptor has a predetermined shape so that the carrier path becomes a straight line for bypassing the interceptors, and
the carrier path is tilted from the shortest distance line.

7. The transistor according to claim 1, wherein
each interceptor has a predetermined shape so that the carrier path becomes a zigzag line for bypassing the interceptors.

8. The transistor according to claim 1, wherein
the interceptors are alternately aligned in two lines,
two lines are parallel each other, and
two lines are perpendicular to the shortest distance line of the carrier path.

9. The transistor according to claim 1, further comprising:
a semiconductor substrate, wherein
the emitter, the base and the collector are disposed on one side of the substrate so that the carrier path is disposed near a surface portion of the substrate.

10. The transistor according to claim 9, wherein
the transistor is a lateral type bipolar transistor.

11. The transistor according to claim 1, further comprising:
a semiconductor substrate, wherein
the emitter, the base and the collector are disposed in the substrate in a vertical direction thereof so that the carrier path is disposed in the substrate vertically.

12. The transistor according to claim 11, wherein
the transistor is a vertical type bipolar transistor.

13. An insulated gate bipolar transistor comprising:
a drift layer having a first conductive type;
a base having a second conductive type and disposed in the drift layer;
an emitter having the first conductive type and disposed in the base;
a collector having the second conductive type and disposed in the drift layer; and
a plurality of interceptors for intercepting a carrier path of a current in the drift layer, wherein
the carrier path is disposed between the emitter and the collector through the base and the drift layer, and
each interceptor is disposed on a shortest distance line of the carrier path in the drift layer between the emitter and the collector.

14. The transistor according to claim 13, further comprising:
a gate disposed on the emitter, the base and the drift layer,
wherein
the base and the collector are separated each other,
the interceptors are alternately aligned in two lines,
one line of the interceptors is disposed under the gate, and
the other line of the interceptors is disposed between the collector and the gate.

15. The transistor according to claim 13, wherein
each interceptor is an insulation region.

16. The transistor according to claim 15, wherein
the insulation region is made of an oxide film.

17. The transistor according to claim 13, wherein
each interceptor has a predetermined shape so that the carrier path becomes a straight line for bypassing the interceptors, and
the carrier path is tilted from the shortest distance line.

18. The transistor according to claim 13, wherein
each interceptor has a predetermined shape so that the carrier path becomes a zigzag line for bypassing the interceptors.

19. The transistor according to claim 13, further comprising:
a semiconductor substrate, wherein
the emitter, the base and the collector are disposed on one side of the substrate so that the carrier path is disposed near a surface portion of the substrate.

20. The transistor according to claim 19, wherein
the transistor is a lateral type insulated gate bipolar transistor.

21. The transistor according to claim 13, wherein
the interceptors are alternately aligned in two lines,
two lines are parallel each other, and
two lines are perpendicular to the shortest distance line of the carrier path.
